(19) United States
(12) Patent Application Publication
(10) Pub. No.: US 2014/0027168 A1
(43) Pub. Date: Jan. 30, 2014

(54) PRINTED WIRING BOARD, PRINTING METHOD, AND LIQUID DEVICE

(71) Applicant: Sony Corporation, Tokyo (JP)

(72) Inventors: YASUHIRO WATANABE, Tokyo (JP); Miki Tsuchiya, Tokyo (JP); Yuichi Takai, Tokyo (JP)

(73) Assignee: Sony Corporation, Tokyo (JP)

(21) Appl. No.: 13/951,615

(22) Filed: Jul. 26, 2013

(30) Foreign Application Priority Data
Jul. 27, 2012 (JP) 2012-166502

(51) Int. Cl. H05K 3/10; H05K 1/02

(52) U.S. Cl. CPC H05K 3/10; H05K 1/0296
USPC 174/262; 101/114; 427/98.4

(57) ABSTRACT

A printed wiring board, in which a pattern is formed by screen printing, includes: a land group including lands each provided corresponding to a through-hole; and a dummy pattern provided in proximity to the land group, and free from electrical connection.

### BACKGROUND

The technology relates to a printed wiring board, a printing method, and a liquid device. In particular, the technology relates to a printed wiring board, a printing method, and a liquid device which allow screen printing to be performed with high accuracy.

Printing methods using screen printing have been known as a method of manufacturing an electronic component by applying a conductive paste or the like to a predetermined point of a printed material such as a printed circuit board.

An off-contact-system printing method has been known as one of such printing methods. In this method, a printed material and a screen plate are placed apart from each other, the screen plate is moved by being pressed with a squeegee, and a predetermined plate-releasing angle is maintained between the printed material and the screen plate while the screen plate is moved.

In such an off-contact-system printing method, a change in shape of a print pattern may occur due to a change in quantity of the printed conductive paste. In order to suppress this change in shape, a technique of making the plate-releasing angle substantially constant has been proposed (see, for example, Japanese Unexamined Patent Application Publication No. 2011-206967). In this technique, the amount of vertical movement of a support section supporting a plate frame of the screen plate and the printed material is changed according to movement of the squeegee, so that the plate-releasing angle is made substantially constant.

According to the technique of Japanese Unexamined Patent Application Publication No. 2011-206967, it is possible to suppress unevenness of a pressure used to press the squeegee into the printed material.

### SUMMARY

In the technique of Japanese Unexamined Patent Application Publication No. 2011-206967, however, it is difficult to adjust the quantity of the applied conductive paste finely for each region of the printed material. Therefore, adhesiveness between the printed material and the screen plate may vary depending on a distribution density of the print pattern, which may result in unevenness in the quantity of the applied conductive paste.

It is desirable to provide a printed wiring board, a printing method, and a liquid device capable of performing screen printing with great precision.

According to an embodiment of the technology, there is provided a printed wiring board in which a pattern is formed by screen printing. The printed wiring board includes: a land group including lands each provided corresponding to a through-hole; and a dummy pattern provided in proximity to the land group, and free from electrical connection.

The dummy pattern may be provided on a part or a whole of periphery of the land group.

The dummy pattern may be provided on both sides of the land group, and may extend in a moving direction of a squeegee in the screen printing.

The lands may have different shapes according to a distribution density of the lands in the land group.

The lands in a region where the distribution density of the lands in the land group is low each may have a shape that may be long in a moving direction of a squeegee in the screen printing.

A positioning hole that allows alignment in the screen printing may be provided at each of diagonally-opposite corners.

According to an embodiment of the technology, there is provided a printing method of a printed wiring board in which a pattern is formed by screen printing. The printing method includes: preparing a land group including lands each formed corresponding to a through-hole; and forming a dummy pattern that is free from electrical connection in proximity to the land group.

According to an embodiment of the technology, there is provided a liquid device, including: a first substrate and a second substrate disposed to face each other; a plurality of wall sections standing next to each other in a first direction in an inner surface of the first substrate, the inner surface facing the second substrate, and the wall sections extending in a second direction different from the first direction; a first electrode and a second electrode provided on a wall surface of each of the wall sections, the first electrode and the second electrode having respective parts facing each other; an insulating film covering each of the first electrode and the second electrode; a third electrode provided on an inner surface of the second substrate, the inner surface facing the first substrate; and a polar liquid and a nonpolar liquid being enclosed between the first substrate and the third electrode, and having respective refractive indexes different from each other. A first through-hole and a second through-hole are provided in a region of the first substrate, in which the region is provided between a pair of the wall sections next to each other. The first electrode is connected to a first leading wiring through the first through-hole, in which the first leading wiring is provided on an outer surface of the first substrate, and the outer surface is opposite to the inner surface of the first substrate. The second electrode is connected to a second leading wiring through the second through-hole, in which the second leading wiring is provided on the outer surface of the first substrate. A dummy pattern that is free from electrical connection is provided in proximity to a land group that includes lands provided corresponding to the first through-hole and the second through-hole.

According to the above-described embodiments of the technology, the dummy pattern that is not electrically connected is formed in proximity to the land group.

According to the above-described embodiments of the technology, the screen printing is allowed to be performed with high accuracy.

It is to be understood that both the foregoing general description and the following detailed description are exemplary, and are intended to provide further explanation of the technology as claimed.

### BRIEF DESCRIPTION OF THE DRAWINGS

The accompanying drawings are included to provide a further understanding of the disclosure, and are incorporated in and constitute a part of this specification. The drawings illustrate embodiments and, together with the specification, serve to describe the principles of the technology.

FIG. 1 is a diagram illustrating an appearance of a liquid device to which an embodiment of the technology is applied.

FIG. 2 is a diagram illustrating a configuration example of the liquid device.

FIG. 3 is a perspective diagram illustrating an appearance of a partition sheet.

FIG. 4 is a cross-sectional diagram used to describe a structure of an electrode of the partition sheet.

FIG. 5 is a diagram illustrating an operation principle of the liquid device.

FIG. 6 is a cross-sectional diagram used to describe a structure of a through-hole of the partition sheet.

FIG. 7 is a diagram used to describe a flow of typical screen printing.

FIG. 8 is a diagram used to describe unevenness of an amount of an applied conductive paste.

FIG. 9 is a diagram used to describe an example of the partition sheet in which a dummy pattern is provided.

FIGS. 10A and 10B are diagrams used to describe details of the dummy pattern in FIG. 9.

FIG. 11 is a diagram used to describe another example of the partition sheet in which a dummy pattern is provided.

FIG. 12 is a diagram used to describe still another example of the partition sheet in which a dummy pattern is provided.

FIG. 13 is a diagram used to describe an example of the partition sheet in which a land shape is changed.

FIGS. 14A and 14B are diagrams used to describe details of the land shape in FIG. 13.

FIG. 15 is a flowchart used to describe screen printing processing.

### DETAILED DESCRIPTION

An embodiment of the technology will be described with reference to the drawings.

### [Configuration Example of Liquid Device]

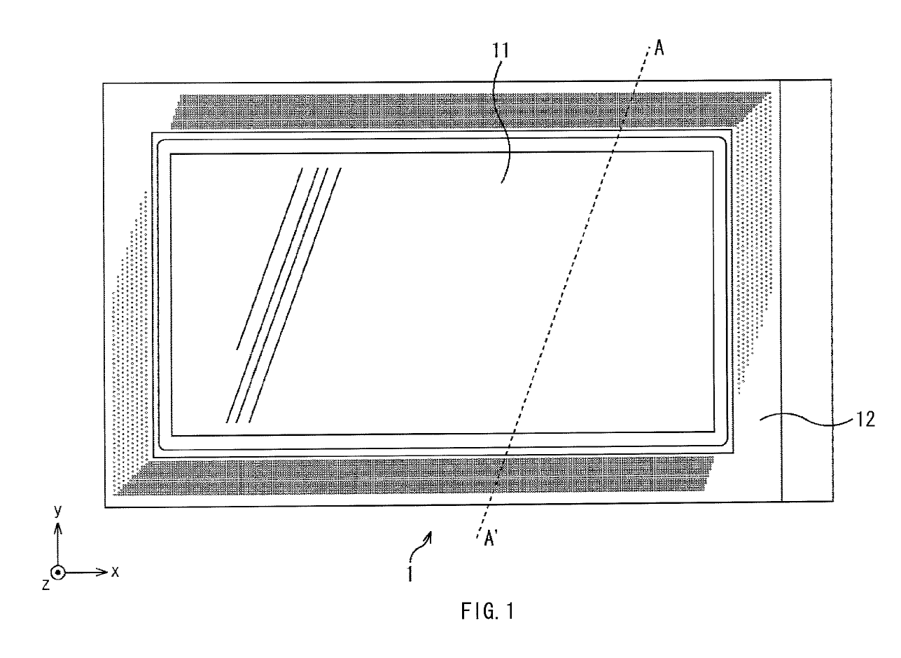

FIG. 1 is an external view illustrating a configuration example of a liquid device (a liquid device 1) to which an embodiment of the technology is applied.

The liquid device is an electro-optical device that causes deformation or displacement of a liquid by using electrowetting of controlling electrostatic wettability, and obtains a desired effect by using this phenomenon.

The liquid device 1 in FIG. 1 includes a display section 11 and a wiring region 12. In the display section 11, a liquid is enclosed. In the wiring region 12, a land (a connection section) used to apply a voltage to the liquid enclosed in the display section 11 is formed.

A plurality of partitions are provided to stand inside of the display section 11. The plurality of partitions extend in a direction parallel to a line segment A-A′ and each have a height in a Z direction. The liquid is partitioned by the partitions next to each other. Further, electrodes are provided on respective surfaces of the partitions next to each other, the respective surfaces facing each other. The liquid partitioned by the partitions is deformed or displaced by a voltage applied between the electrodes through the connection section provided in the wiring region 12.

In the inside of the display section 11, the liquid partitioned off by the partitions next to each other functions as one lens extending in the direction parallel with the line segment A-A′. The liquid device 1 functions as a Fresnel lens including a plurality of lenses each equivalent to this one lens.

It is to be noted that the liquid device 1 is also allowed to function as a lenticular lens, by causing the liquid partitioned off by the partitions next to each other to function as a cylindrical lens.

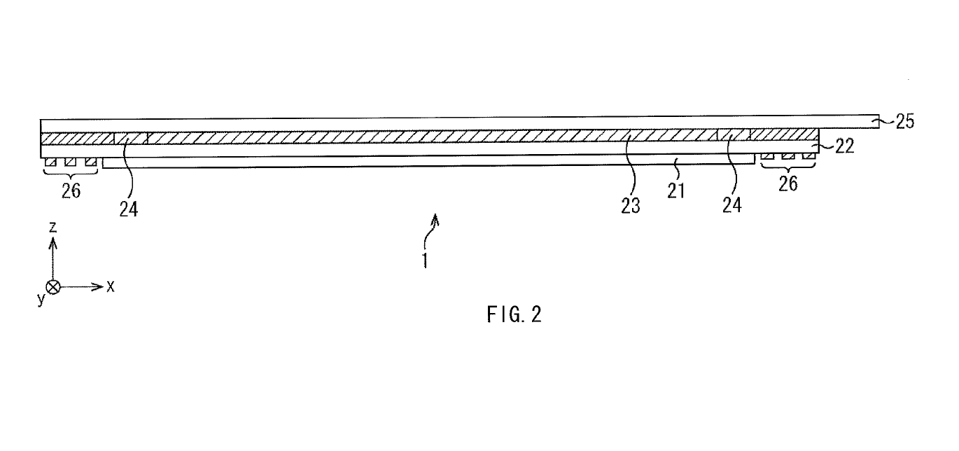

Next, a detailed configuration example of the liquid device 1 in FIG. 1 will be described with reference to FIG. 2.

The liquid device 1 in FIG. 2 includes a base glass 21, a partition sheet 22, a liquid 23, a liquid sealing section 24, a cover glass 25, and a connection section 26.

The base glass 21 is configured using a transparent glass that allows visible light to pass therethrough. The base glass 21 may be a transparent insulating material that allows visible light to pass therethrough. The base glass 21 may be configured using, for example, a transparent plastic.

The partition sheet 22 is configured as a first substrate, and disposed to face the cover glass 25 with the liquid 23 provided therebetween. The partition sheet 22 has an inner surface (a surface on a side where the liquid 23 is provided) facing the cover glass 25. On this inner surface, the plurality of partitions are provided to stand next to each other in a direction orthogonal to the line segment A-A′ in FIG. 1, and extend in the direction parallel to the line segment A-A′.

The liquid 23 is a liquid that is deformed or displaced in response to application of a voltage, and is sealed by the liquid sealing section 24 and the cover glass 25.

The cover glass 25 is configured as a second substrate, and disposed to face the partition sheet 22 with the liquid 23 provided therebetween. The cover glass 25 is configured using a transparent glass that allows visible light to pass therethrough. The cover glass 25 as well may be a transparent insulating material that allows visible light to pass therethrough. The cover glass 25 may be configured using, for example, a transparent plastic.

The connection section 26 is electrically connected to a wiring (a leading wiring) not illustrated, corresponding to the connection section provided in the wiring region 12 in FIG. 1.

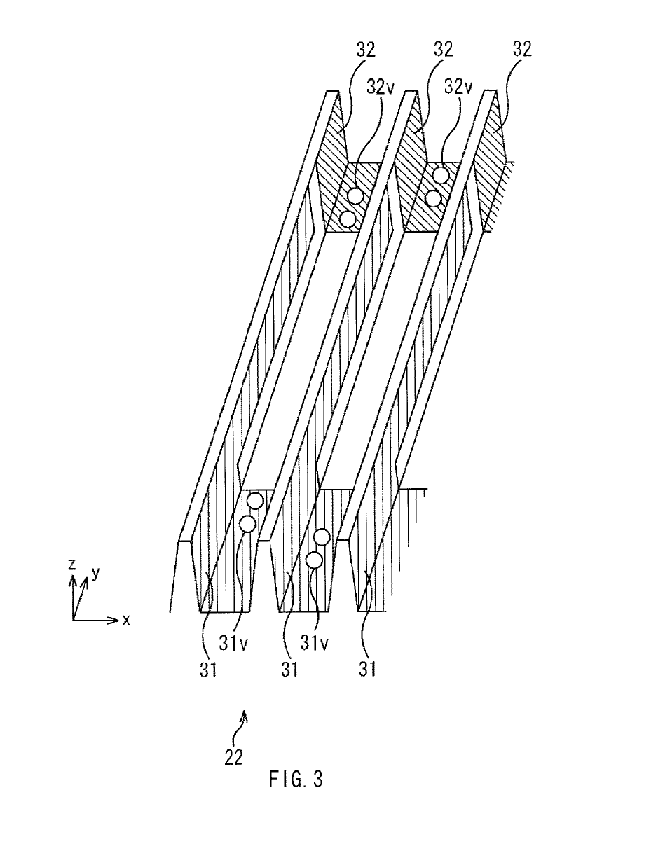

FIG. 3 is a perspective diagram illustrating an appearance of the partition sheet 22.

FIG. 3 illustrates three of the partitions standing next to each other in the direction orthogonal to the line segment A-A′ in FIG. 1, and extending in the direction parallel to the line segment A-A′.

On a wall surface of each of the partitions, a first electrode 31 and a second electrode 32 are provided. The first electrode 31 and the second electrode 32 are disposed to extend along an extending direction of the partition, and have respective parts facing each other. Further, at one end of a region provided between the partitions next to each other, a first through-hole 31v is formed to pass through the partition sheet 22 in a thickness direction (the Z direction). At the other end of the region provided between the partitions next to each other, a second through-hole 32v is formed to pass through the partition sheet 22 in the thickness direction (the Z direction).

Each of the first electrodes 31 is connected to a not-illustrated first leading wiring, through the first through-hole 31v. Each of the second electrodes 32 is connected to a not-illustrated second leading wiring, through the second through-hole 32v. In other words, the first through-hole 31v is provided for the first electrode 31, and the second through-hole 32v is provided for the second electrode 32.

Examples of a material forming each of the first electrode 31, the second electrode 32, the not-illustrated first leading wiring, and the not-illustrated second leading wiring may include transparent conductive materials such as ITO (Indium Tin Oxide) and ZnO, metallic materials such as Cu, and conductive materials such as C (carbon) and electroconductive polymer.

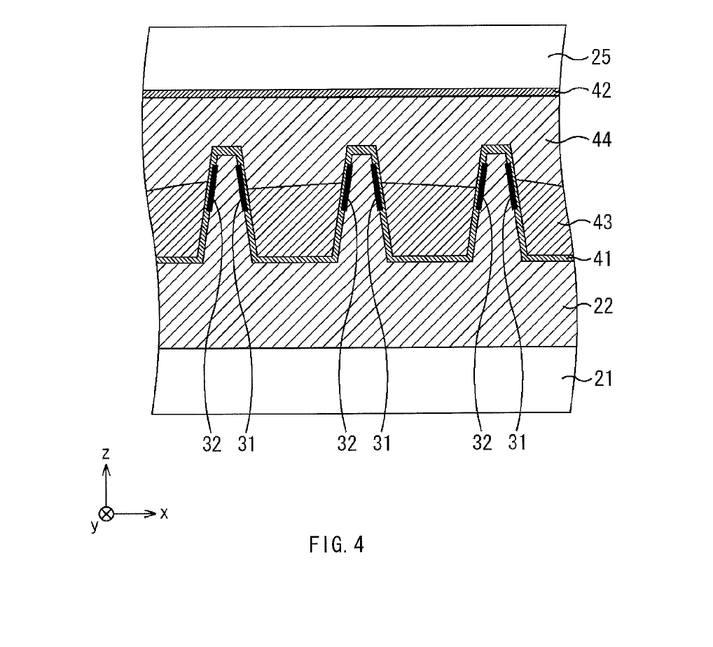

FIG. 4 is a cross-sectional diagram used to describe a structure including the first electrode 31 and the second electrode 32 facing each other in the partition sheet 22, as well as a part present in proximity thereto.

As illustrated in FIG. 4, the first electrode 31 and the second electrode 32 are covered by an insulating film 41. Further, a third electrode 42 is provided on an inner surface of the cover glass 25, the inner surface facing the partition sheet 22. Examples of a material of the third electrode 42 may include transparent conductive materials such as ITO and ZnO.

Furthermore, a nonpolar liquid 43 and a polar liquid 44 are enclosed in a space region sealed by the partition sheet 22 and the cover glass 25. The nonpolar liquid 43 and the polar liquid 44 are present while being separated from each other without dissolving in each other in the closed space, and form an interface. The nonpolar liquid 43 and the polar liquid 44 are transparent, and a light ray passing through the interface is refracted according to an entry angle thereof and a refractive index of each of the nonpolar liquid 43 and the polar liquid 44.

The nonpolar liquid 43 is a liquid material having almost no polarity and indicating electric insulation, and, for example, a silicone oil may be used as this material. It is to be noted that the nonpolar liquid 43 may be, for example, a hydrogen-carbonate-based material such as decane and dodecane.

The polar liquid 44 is a liquid material having polarity. Usable examples of this material may include, besides water, a water solution in which an electrolyte such as lithium chloride, potassium chloride, or sodium chloride is dissolved. When a voltage is applied to the polar liquid 44, wettability for the wall surface of the partition (a contact angle between the polar liquid 44 and the wall surface of the partition) changes greatly, as compared with that of the nonpolar liquid 43. The polar liquid 44 is in contact with the third electrode 42.

Further, when a voltage is applied between the first electrode 31 and the second electrode 32, a curvature of the interface becomes small. When a voltage equal to or higher than a certain level is applied, the interface becomes flat.

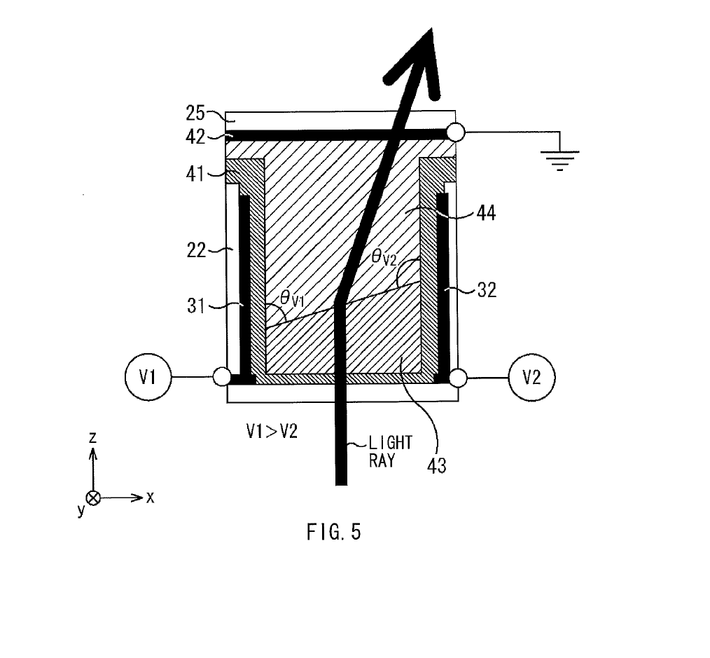

Specifically, suppose an electric potential of the first electrode 31 is V1, an electric potential of the second electrode 32 is V2, the third electrode is an earth electrode, a contact angle of the polar liquid 44 with respect to one of the wall surfaces of the partition is θV1, and a contact angle of the polar liquid 44 with respect to the other of the wall surfaces of the partition is θV2. When the electric potential V1 is greater than the electric potential V2 (V1>V2), the contact angle θV1 is smaller than the contact angle θV2 (θV1<θV2) as illustrated in FIG. 5.

Further, although not illustrated, when the electric potential V2 is greater than the electric potential V1 (V1<V2), the contact angle θV2 is smaller than the contact angle θV1 (θV1>θV2), and when the electric potential V1 and the electric potential V2 are equal to each other (V1=V2), the contact angles θV1 and θV2 are both right angles (90 degrees).

When the electric potential V1 and the electric potential V2 are different (V1≠V2), for example, an incident light ray traveling in the Z direction may be refracted at the interface to be deflected within an XZ plane, as illustrated in FIG. 5. Therefore, it is possible to deflect a light ray to a predetermined direction within the XZ plane, by adjusting the magnitude of each of the electric potential V1 and the electric potential V2.

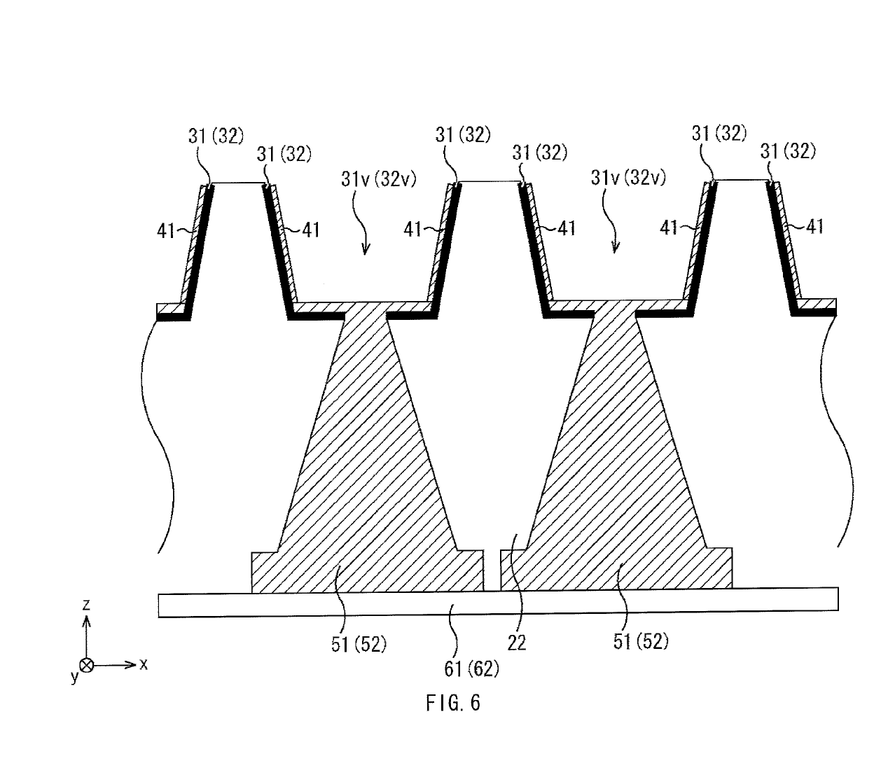

FIG. 6 is a cross-sectional diagram used to describe a structure including the first through-hole 31v and the second through-hole 32v in the partition sheet 22, as well as a part present in proximity thereto.

The first through-hole 31v and the second through-hole 32v are provided with a first connection section 51 and a second connection section 52 filling the inside of these through-holes, respectively, as illustrated in FIG. 6. Thus, the first electrode 31 is connected to a first leading wiring 61 by the first connection section 51, and the second electrode 32 is connected to a second leading wiring 62 by the second connection section 52.

The first connection section 51 and the second connection section 52 filling the inside of the first through-hole 31v and the second through-hole 32v, respectively, are formed by applying a conductive paste to a part corresponding to the first through-hole 31v and the second through-hole 32v from a back surface (a lower side in FIG. 6) of the partition sheet 22, by screen printing. The conductive paste may be a thermosetting or ultraviolet curable Ag paste or a carbon paste.

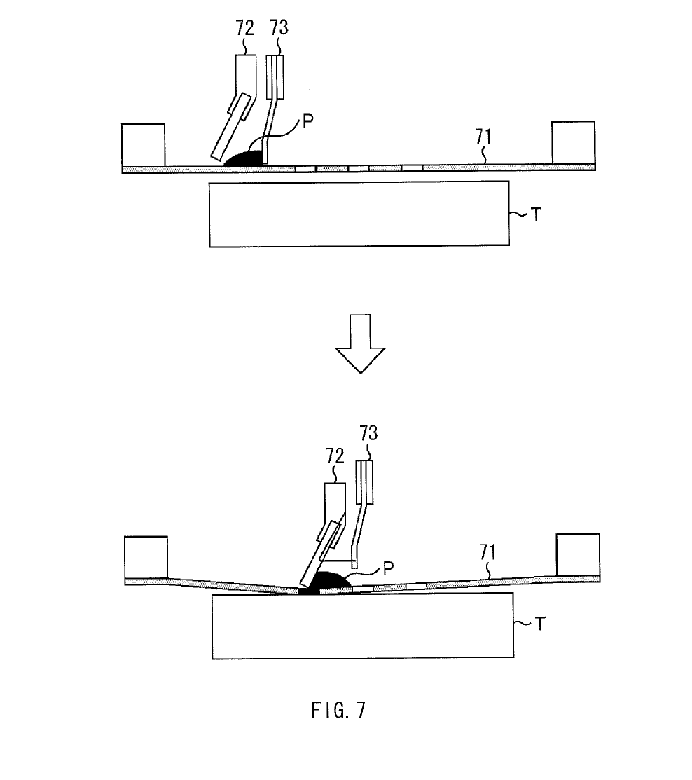

Here, a flow of typical screen printing will be described with reference to FIG. 7.

FIG. 7 illustrates a screen printing apparatus that performs screen printing of a conductive paste P on a printed material T.

In the screen printing apparatus in FIG. 7, the conductive paste P is prepared on a screen plate 71. The screen plate 71 is provided with an opening section corresponding to a print target region of the printed material T. A squeegee 72 and a scraper 73 are moved in a rightward direction in FIG. 7, while the tip of the squeegee 72 is pressed against the screen plate 71. As a result, the conductive paste P is pushed out to the print target region of the printed material T, through the opening section of the screen plate 71. The conductive paste P is thereby printed in the print target region of the printed material T.

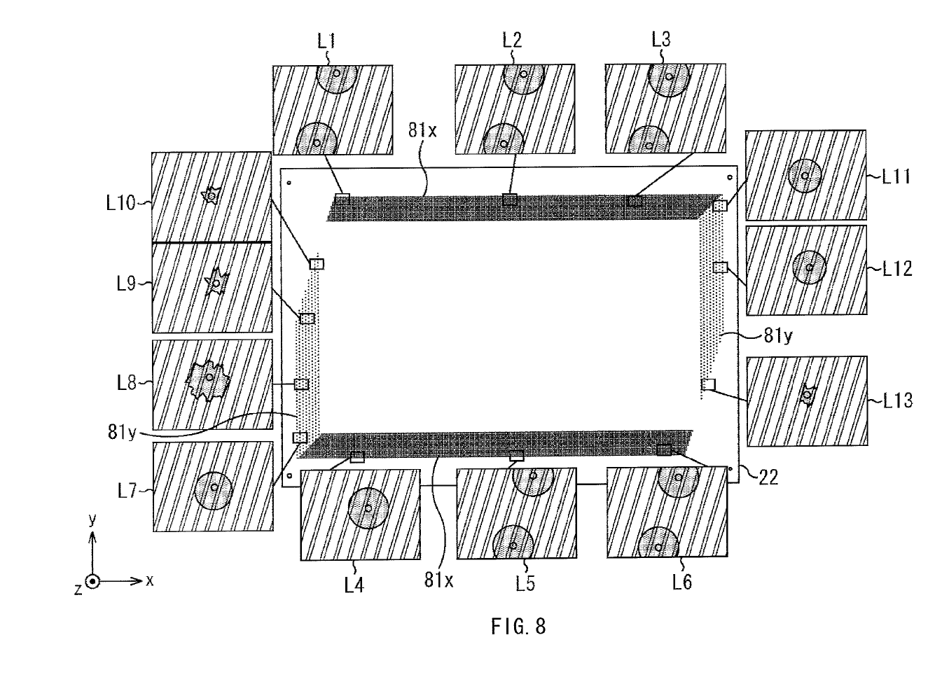

The land (the connection section) is formed by applying the conductive paste to the part corresponding to the first through-hole 31v and the second through-hole 32v of the partition sheet 22, through such screen printing. However, variations in land shape may occur depending on the positions of the first through-hole 31v and the second through-hole 32, as illustrated in FIG. 8.

In the partition sheet 22 illustrated in FIG. 8, land groups 81x and 81y are formed by applying the conductive paste from the back-surface side of the partition sheet 22 by the screen printing and pushing out the conductive paste through the first through-hole 31v and the second through-hole 32v. It is to be noted that, in the screen printing for the partition sheet 22, a squeegee extending in a lateral direction (an x-axis direction) in FIG. 8 is assumed to move in a vertical direction (a y-axis direction) in FIG. 8.

Here, assuming that enlarged views of lands at predetermined positions of the land groups 81x and 81y are L1 to L13, each land in the land group 81x is formed to have a fine circular shape as illustrated in the enlarged views L1 to L6. On the other hand, each land in the land group 81y is formed to have a distorted shape as illustrated in the enlarged views L8 to L13. In particular, each of the lands illustrated in the enlarged views L9, L10, and L13 has a small diameter, in addition to having the distorted shape.

This is due to a difference in land distribution density between the land groups 81x and 81y. Specifically, the land distribution density in the land group 81y is low, as compared with the land distribution density in the land group 81x.

When the conductive paste is applied to the region corresponding to the land group 81x in the partition sheet 22 by the squeegee, since the land distribution density is high, adhesiveness between the partition sheet 22 and the screen plate is also high. Therefore, a sufficient amount of the conductive paste is applied, and the amount of the conductive paste to be pushed out through the through-holes is also sufficient.

On the other hand, when the conductive paste is applied to the region corresponding to the land group 81y in the partition sheet 22 by the squeegee, since the land distribution density is low, the adhesiveness between the partition sheet 22 and the screen plate is also low. Therefore, a sufficient amount of the conductive paste is not applied, and the amount of the conductive paste to be pushed out through the through-holes is small. As a result, poor conduction occurs.

Thus, a configuration of enhancing the adhesiveness between the partition sheet 22 and the screen plate will be described below.

[First Configuration of Partition Sheet with Added Dummy Pattern]

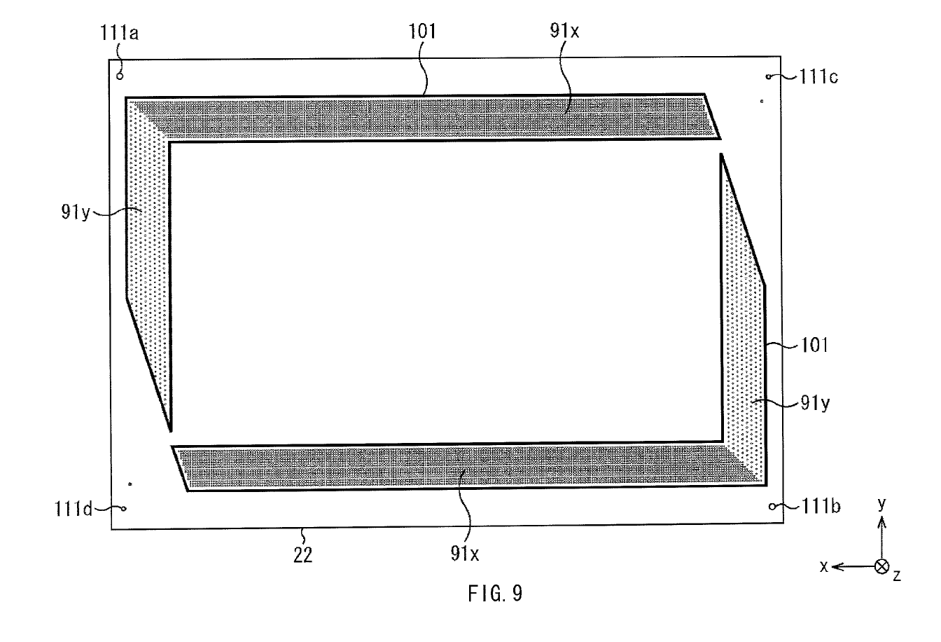

First, an example of the partition sheet 22 in which a dummy pattern is provided to enhance the adhesiveness between the partition sheet 22 and the screen plate will be described with reference to FIG. 9.

FIG. 9 illustrates a pattern of the partition sheet 22 when viewed from the back surface. In other words, in the screen printing, the conductive paste is applied to a surface, which is illustrated in FIG. 9, of the partition sheet 22.

In the partition sheet 22, a land group 91x and a land group 91y are formed corresponding to the first through-hole 31v and the second through-hole 32v. The land group 91x is a group of lands forming a strip extending in an x direction, and the land group 91y is a group of lands forming a strip extending in a y direction, as illustrated in FIG. 9.

Further, in the partition sheet 22, a dummy pattern 101 that is not electrically connected is formed in proximity to the land groups 91x and 91y. Specifically, the dummy pattern 101 is formed on the periphery of the land groups 91x and 91y.

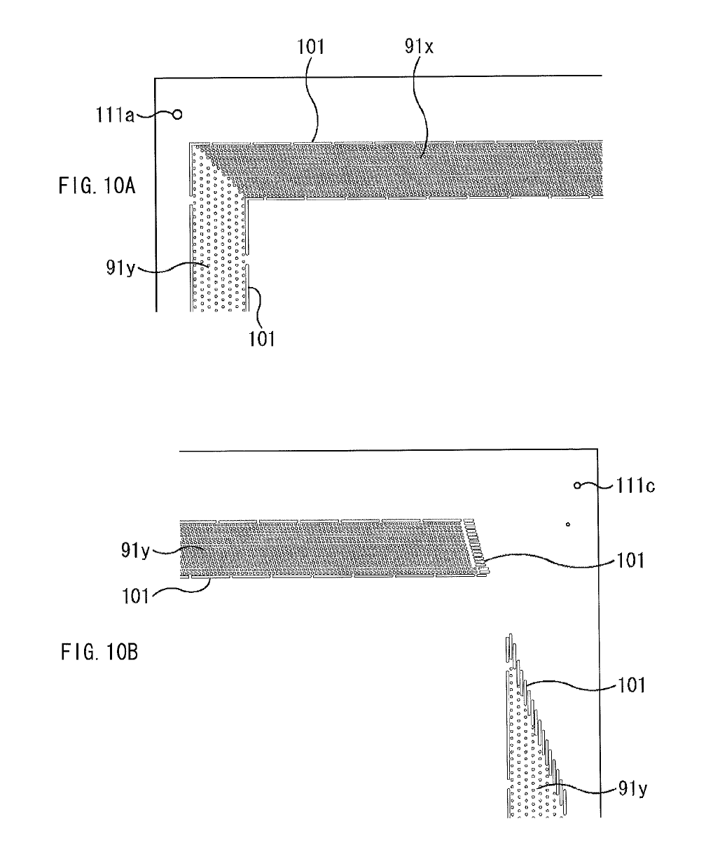

FIGS. 10A and 10B are diagrams illustrating details of the dummy pattern 101 in FIG. 9.

As illustrated in FIG. 10A, a plurality of dummy patterns 101 each having a predetermined length are aligned along an outer boundary of the land groups 91x and 91y. Further, as illustrated in FIG. 10B, at an end part of each of the land groups 91x and 91y, the plurality of dummy patterns 101, which each have a predetermined length in a longitudinal direction of each of the land groups 91x and 91y, are aligned to match with the shape of the end part of each of the land groups 91x and 91y.

Furthermore, as illustrated in FIG. 9, positioning holes 111a and 111b used for alignment in the screen printing are provided at diagonally-opposite corners of the partition sheet 22. Similar positioning holes 111c and 111d are also provided likewise.

As described above, the dummy patterns 101 are formed on the periphery of the land groups 91x and 91y. Thus, in the partition sheet 22, the adhesiveness between the partition sheet 22 and the screen plate at the time of the screen printing is allowed to be enhanced in the region corresponding to the land group 91y, by the squeegee. This makes it possible to apply a sufficient amount of the conductive paste, thereby allowing the amount of the conductive paste pushed out through the through-holes to be sufficient. In other words, the screen printing is allowed to be performed with high precision, and as a result, it is possible to suppress occurrence of poor conduction.

It is to be noted that although the above-described dummy patterns 101 are formed on the entire periphery of the land groups 91x and 91y, the dummy patterns 101 may be formed on a part of the periphery of the land groups 91x and 91y. For example, the dummy patterns 101 may be formed on only a part of the land group 91y, on which part the land distribution density is low.

Moreover, as described with reference to FIG. 10A, when, for example, the length of the dummy patterns 101 aligned on the periphery of the land groups 91x and 91y is made equal to the length of ten lands, lands with poor conduction are allowed to be readily identified (easily counted) at the time of conduction confirmation.

[Second Configuration of Partition Sheet with Added Dummy Pattern]

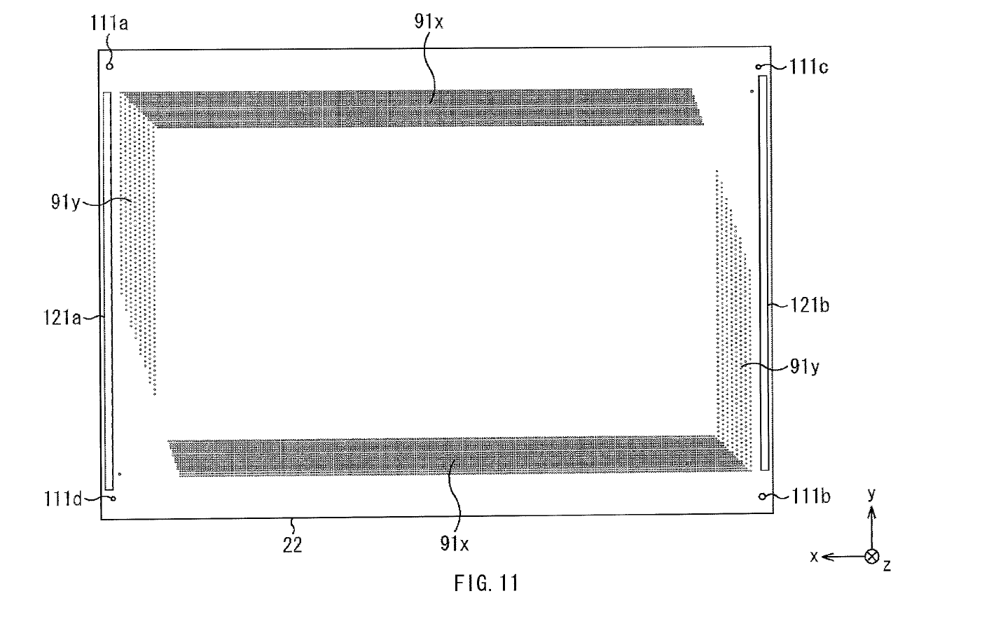

Next, another example of the partition sheet 22 in which a dummy pattern is provided to enhance the adhesiveness between the partition sheet 22 and the screen plate will be described with reference to FIG. 11.

In a manner similar to FIG. 9, corresponding to the first through-hole 31v and the second through-hole 32v, a land group 91x and a land group 91y are formed in the partition sheet 22. The land group 91x is a group of lands forming a strip extending in an x direction, and the land group 91y is a group of lands forming a strip extending in a y direction, as illustrated in FIG. 11.

Further, in the partition sheet 22, dummy patterns 121a and 121b which are not electrically connected are formed in proximity to the land groups 91x and 91y. Specifically, the dummy patterns 121a and 121b are formed on both sides of the land groups 91x and 91y, to extend in a moving direction (a y-axis direction) of the squeegee in the screen printing.

Furthermore, in a manner similar to FIG. 9, positioning holes 111a and 111b used for alignment in the screen printing are provided at diagonally-opposite corners of the partition sheet 22, as illustrated in FIG. 11. Similar positioning holes 111c and 111d are also provided likewise.

As described above, the dummy patterns 121a and 121b are formed on both sides of the land group 91y, to extend in the moving direction of the squeegee in the screen printing. Thus, in the partition sheet 22, the adhesiveness between the partition sheet 22 and the screen plate at the time of the screen printing is allowed to be enhanced in the region corresponding to the land group 91y, by the squeegee. This makes it possible to apply a sufficient amount of the conductive paste, thereby allowing the amount of the conductive paste pushed out through the through-holes to be sufficient. In other words, the screen printing is allowed to be performed with high precision, and as a result, it is possible to suppress occurrence of poor conduction.

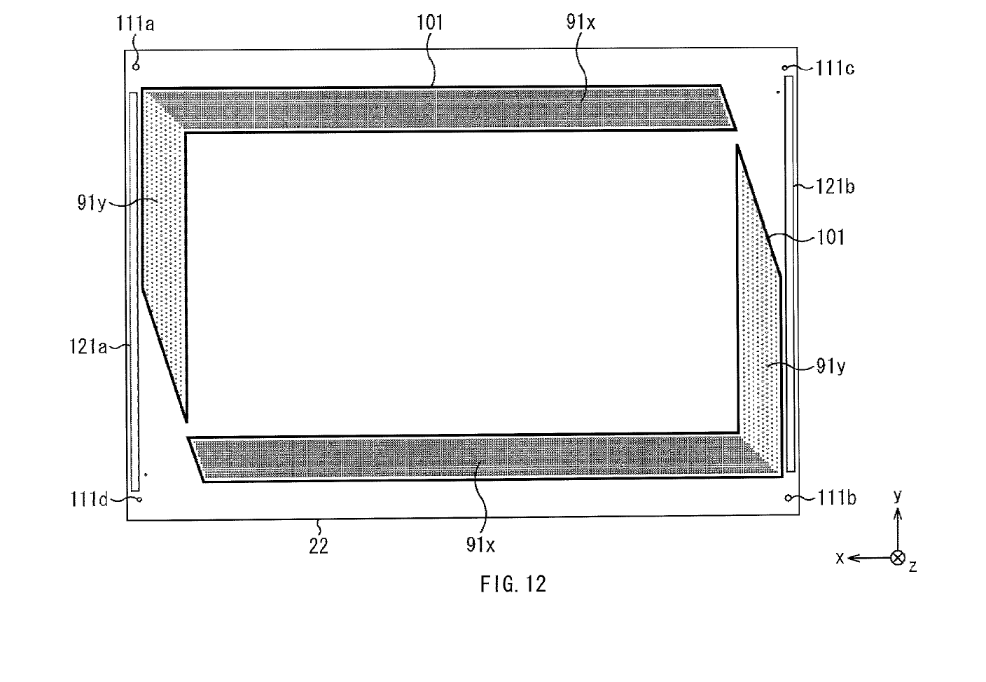

It is to be noted that, as illustrated in FIG. 12, the dummy patterns 121a and 121b may be additionally formed in the partition sheet 22 in which the dummy patterns 101 described with reference to FIG. 9 are formed.

Some examples in which the adhesiveness between the partition sheet 22 and the screen plate is enhanced by providing the dummy pattern have been described above. Now, an example in which the adhesiveness between the partition sheet 22 and the screen plate is enhanced by changing the shape of the land will be described below.

[Configuration of Partition Sheet with Changed Shape of Land]

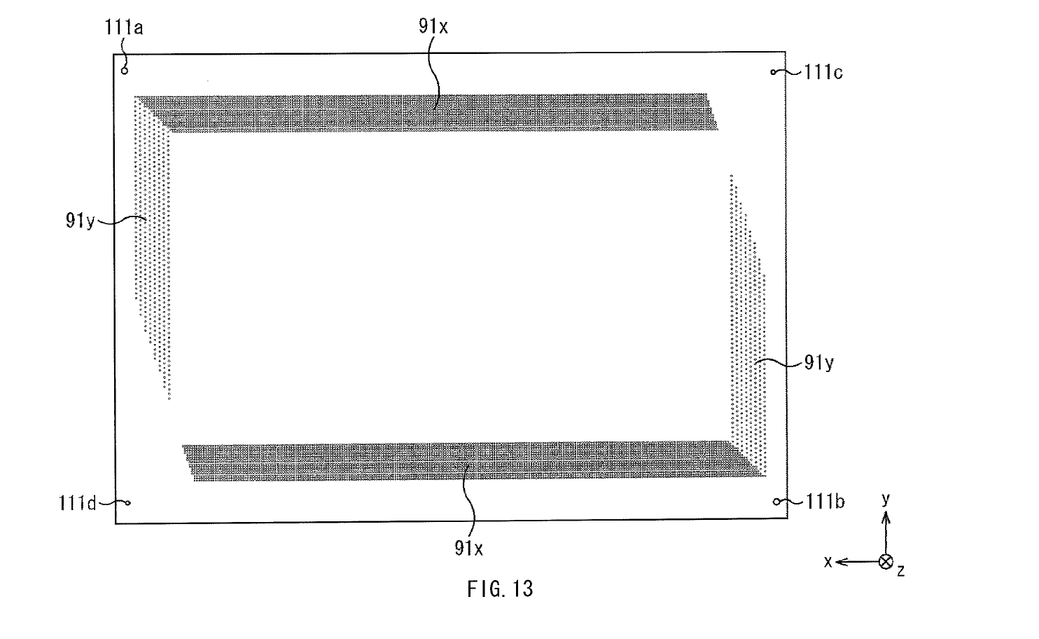

FIG. 13 is a diagram used to describe the partition sheet 22 in which the shape of the land is changed to enhance the adhesiveness between the partition sheet 22 and the screen plate.

In a manner similar to FIG. 9, in the partition sheet 22, a land group 91x and a land group 91y are formed corresponding to the first through-hole 31v and the second through-hole 32v. The land group 91x is a group of lands forming a strip extending in an x direction, and the land group 91y is a group of lands forming a strip extending in a y direction, as illustrated in FIG. 13.

It is to be noted that, in this example, each land in the land group 91y is formed to have a shape different from that of each land in the land group 91x.

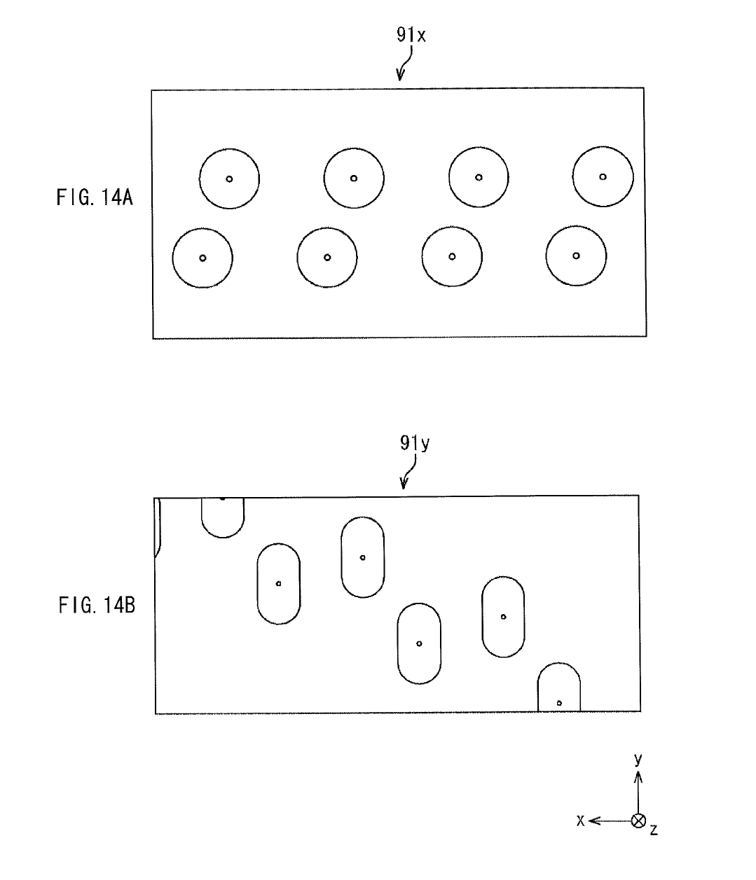

Specifically, the shape of each land in the land group 91x is a circle as illustrated in FIG. 14A, whereas the shape of each land in the land group 91y is an oblong (i.e. a rounded rectangle) that is long in the moving direction of the squeegee in the screen printing as illustrated in FIG. 14B. In other words, in the land groups 91x and 91y, each land in a region where the land distribution density is low is formed to have a shape that is long in the moving direction of the squeegee in the screen printing. It is to be noted that each land in the land group 91y may be shaped like an oval or egg which is long in the moving direction of the squeegee in the screen printing.

Further, in a manner similar to FIG. 9, positioning holes 111a and 111b used for alignment in the screen printing are provided at diagonally-opposite corners of the partition sheet 22, as illustrated in FIG. 13. Similar positioning holes 111c and 111d are also provided likewise.

As described above, each land in the region where the land distribution density is low is formed to have the shape that is long in the moving direction of the squeegee in the screen printing. Thus, in the partition sheet 22, the adhesiveness between the partition sheet 22 and the screen plate at the time of the screen printing is allowed to be enhanced in the region corresponding to the land group 91y, by the squeegee. This makes it possible to apply a sufficient amount of the conductive paste, thereby allowing the amount of the conductive paste pushed out through the through-holes to be sufficient. In other words, the screen printing is allowed to be performed with high precision, and as a result, it is possible to suppress occurrence of poor conduction.

It is to be noted that the land having the shape described with reference to FIG. 14B may be applied to each land in the land group 91y of the partition sheet 22 in any of FIGS. 9, 11, and 12.

### [Screen Printing Processing]

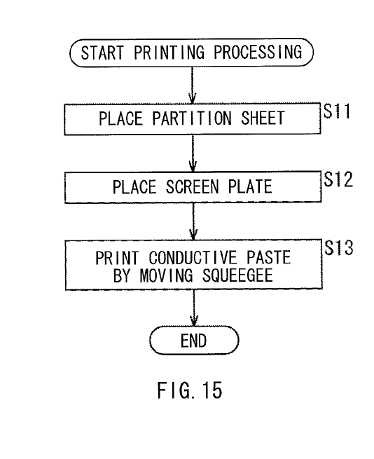

Next, processing of printing the conductive paste for the partition sheet 22 described above will be described with reference to a flowchart in FIG. 15.

In step S11, the partition sheet 22 is placed in the screen printing apparatus, with a printed surface (the back surface) thereof facing upward.

In step S12, the screen plate is placed to cover the print target region of the partition sheet 22. At this moment, the positions of the partition sheet 22 and the screen plate are determined using the positioning holes 111a and 111b or the positioning holes 111c and 111d provided at the diagonally-opposite corners of the partition sheet 22.

In step S13, the screen printing apparatus prints the conductive paste on the print target region, by moving the squeegee. As a result, in addition to the land groups 91x and 91y, the dummy patterns 101 and/or the dummy patterns 121a and 121b are formed. Further, the land group 91y may be formed to have the shape that is long in the moving direction of the squeegee.

According to the above-described processing, in the partition sheet 22, the adhesiveness between the partition sheet 22 and the screen plate at the time of the screen printing is allowed to be enhanced in the region corresponding to the land group 91y, by the squeegee. This makes it possible to apply a sufficient amount of the conductive paste, thereby allowing the amount of the conductive paste pushed out through the through-holes sufficient to be sufficient. In other words, the screen printing is allowed to be performed with high precision, and, as a result, occurrence of poor conduction is allowed to be suppressed.

In addition, according to the above-described processing, the screen printing is allowed to be performed on fixed printing conditions, without adjusting printing conditions (such as a printing pressure, an angle, and a speed of the squeegee) in the screen printing apparatus, in other words, without performing delicate control.

It is to be noted that the technology is applied to the partition sheet of the liquid device in the above description, but is not limited thereto. The technology is applicable to any other types of printed wiring boards in which a pattern is formed by screen printing.

Moreover, the technology is not limited to the above-described embodiment, and may be variously modified without deviating from the gist of the technology.

Furthermore, the technology encompasses any possible combination of some or all of the various embodiments described herein and incorporated herein.

It is possible to achieve at least the following configurations from the above-described example embodiments of the disclosure.

(1) A printed wiring board in which a pattern is formed by screen printing, the printed wiring board including:

a land group including lands each provided corresponding to a through-hole; and

a dummy pattern provided in proximity to the land group, and free from electrical connection.

(2) The printed wiring board according to (1), wherein the dummy pattern is provided on a part or a whole of periphery of the land group.
(3) The printed wiring board according to (1) or (2), wherein the dummy pattern is provided on both sides of the land group, and extends in a moving direction of a squeegee in the screen printing.
(4) The printed wiring board according to any one of (1) to (3), wherein the lands have different shapes according to a distribution density of the lands in the land group.
(5) The printed wiring board according to (4), wherein the lands in a region where the distribution density of the lands in the land group is low each have a shape that is long in a moving direction of a squeegee in the screen printing.
(6) The printed wiring board according to any one of (1) to (5), wherein a positioning hole that allows alignment in the screen printing is provided at each of diagonally-opposite corners.
(7) A printing method of a printed wiring board in which a pattern is formed by screen printing, the printing method including:

preparing a land group including lands each formed corresponding to a through-hole; and

forming a dummy pattern that is free from electrical connection in proximity to the land group.

(8) A liquid device, including:

a first substrate and a second substrate disposed to face each other;

a plurality of wall sections standing next to each other in a first direction in an inner surface of the first substrate, the inner surface facing the second substrate, and the wall sections extending in a second direction different from the first direction;

a first electrode and a second electrode provided on a wall surface of each of the wall sections, the first electrode and the second electrode having respective parts facing each other;

an insulating film covering each of the first electrode and the second electrode;

a third electrode provided on an inner surface of the second substrate, the inner surface facing the first substrate; and

a polar liquid and a nonpolar liquid being enclosed between the first substrate and the third electrode, and having respective refractive indexes different from each other, wherein

a first through-hole and a second through-hole are provided in a region of the first substrate, the region being provided between a pair of the wall sections next to each other,

the first electrode is connected to a first leading wiring through the first through-hole, the first leading wiring being provided on an outer surface of the first substrate, and the outer surface being opposite to the inner surface of the first substrate,

the second electrode is connected to a second leading wiring through the second through-hole, the second leading wiring being provided on the outer surface of the first substrate, and

a dummy pattern that is free from electrical connection is provided in proximity to a land group, the land group including lands provided corresponding to the first through-hole and the second through-hole.

The disclosure contains subject matter related to that disclosed in Japanese Priority Patent Application JP 2012-166502 filed in the Japan Patent Office on Jul. 27, 2012, the entire content of which is hereby incorporated by reference.

It should be understood by those skilled in the art that various modifications, combinations, sub-combinations, and alterations may occur depending on design requirements and other factors insofar as they are within the scope of the appended claims or the equivalents thereof.

What is claimed is:

1. A printed wiring board in which a pattern is formed by screen printing, the printed wiring board comprising:
a land group including lands each provided corresponding to a through-hole; and
a dummy pattern provided in proximity to the land group, and free from electrical connection.

2. The printed wiring board according to claim 1, wherein the dummy pattern is provided on a part or a whole of periphery of the land group.

3. The printed wiring board according to claim 1, wherein the dummy pattern is provided on both sides of the land group, and extends in a moving direction of a squeegee in the screen printing.

4. The printed wiring board according to claim 1, wherein the lands have different shapes according to a distribution density of the lands in the land group.

5. The printed wiring board according to claim 4, wherein the lands in a region where the distribution density of the lands in the land group is low each have a shape that is long in a moving direction of a squeegee in the screen printing.

6. The printed wiring board according to claim 1, wherein a positioning hole that allows alignment in the screen printing is provided at each of diagonally-opposite corners.

7. A printing method of a printed wiring board in which a pattern is formed by screen printing, the printing method comprising:
preparing a land group including lands each formed corresponding to a through-hole; and
forming a dummy pattern that is free from electrical connection in proximity to the land group.

8. A liquid device, comprising:
a first substrate and a second substrate disposed to face each other;
a plurality of wall sections standing next to each other in a first direction in an inner surface of the first substrate, the inner surface facing the second substrate, and the wall sections extending in a second direction different from the first direction;
a first electrode and a second electrode provided on a wall surface of each of the wall sections, the first electrode and the second electrode having respective parts facing each other;
an insulating film covering each of the first electrode and the second electrode;
a third electrode provided on an inner surface of the second substrate, the inner surface facing the first substrate; and
a polar liquid and a nonpolar liquid being enclosed between the first substrate and the third electrode, and having respective refractive indexes different from each other, wherein
a first through-hole and a second through-hole are provided in a region of the first substrate, the region being provided between a pair of the wall sections next to each other,
the first electrode is connected to a first leading wiring through the first through-hole, the first leading wiring being provided on an outer surface of the first substrate, and the outer surface being opposite to the inner surface of the first substrate,
the second electrode is connected to a second leading wiring through the second through-hole, the second leading wiring being provided on the outer surface of the first substrate, and
a dummy pattern that is free from electrical connection is provided in proximity to a land group, the land group including lands provided corresponding to the first through-hole and the second through-hole.
